(19) United States
(12) Patent Application Publication
(10) Pub. No.: US 2013/0093472 A1
(43) Pub. Date: Apr. 18, 2013

(54) SEMICONDUCTOR INTEGRATED CIRCUIT

(71) Applicants: Hae Uk LEE, Icheon-si (KR); Chang Hyuk LEE, Icheon-si (KR); Jae Yong CHA, Icheon-si (KR); Ha Min SUNG, Icheon-si (KR); Yi Seul PARK, Icheon-si (KR)

(72) Inventors: Hae Uk LEE, Icheon-si (KR); Chang Hyuk LEE, Icheon-si (KR); Jae Yong CHA, Icheon-si (KR); Ha Min SUNG, Icheon-si (KR); Yi Seul PARK, Icheon-si (KR)

(73) Assignee: HYNIX SEMICONDUCTOR INC., Icheon-si (KR)

(21) Appl. No.: 13/340,811

(22) Filed: Dec. 30, 2011

(30) Foreign Application Priority Data
Oct. 18, 2011 (KR) 10-2011-0106163

(51) Int. Cl. H03K 3/01

(52) U.S. Cl. 327/108

(57) ABSTRACT

A semiconductor integrated circuit includes a driving unit, a first current path and a second current path. The driving unit applies a power supply voltage to a drive node in response to a control signal. The first current path couples the drive node and an output node. The second current path couples the drive node and the output node. The first current path and the second current path are coupled in parallel between the drive node and the output node.

### CROSS-REFERENCES TO RELATED APPLICATION

The present application claims priority under 35 U.S.C. §119(a) to Korean application number 10-2011-0106163, filed on Oct. 18, 2011, in the Korean Intellectual Property Office, which is incorporated herein by reference in its entirety.

### BACKGROUND

1. Technical Field

The present invention relates generally to a semiconductor integrated circuit, and more particularly to a semiconductor integrated circuit considering electro-migration.

2. Related Art

In general, the electro-migration (hereinafter, referred to EM) refers to migration of metal ions generated when a current is passed through a metal. The EM may deform the structure of a semiconductor integrated circuit. That is, as current is flowing in the circuit, i.e., moving electrons are transferred to, for example, metal component of the circuit, this may cause particles composing the metal component to move from their original position. Over time this force knocks a significant number of particles far from their original positions. As a result, the structure of the metal component of the semiconductor integrated circuit may be deformed. The deformation of the metal structure by the EM reduces the reliability of the semiconductor integrated circuit.

FIG. 1 schematically illustrates a configuration of a driving circuit used in a known semiconductor integrated circuit. In FIG. 1, the driving circuit includes first to fourth transistors P1 to P4 and first to fourth resistors R1 to R4. The first to fourth transistors P1 to P4 have sources configured to receive a power supply voltage VCC, drains coupled to the first to fourth resistors R1 to R4, respectively, and gates configured to receive a control signal PU. The first to fourth transistors P1 to P4 apply the power supply voltage VCC to the first to fourth resistors R1 to R4 in response to the control signal PU. When the power supply voltage VCC is applied by the first to fourth transistors P1 to P4, a current is passed to a pad PAD through the first to fourth resistors R1 to R4.

FIG. 2 illustrates the layout of the driving circuit of FIG. 1. Referring to FIG. 2, the first to fourth transistors P1 to P4 and the first to fourth resistors R1 to R4 are electrically coupled through contacts C1, respectively. Similarly, the first to resistors R1 to R4 and the pad PAD are electrically coupled through contacts C2, respectively.

When the first to fourth transistors P1 to P4 are turned on by the control signal PU, a considerable amount of current is passed to the pad PAD from the first to fourth transistors P1 to P4. Therefore, the contacts C1 and C2 formed of a metal may be deformed by EM. In particular, when the amount of current is larger than a permissible amount of current per unit width of each layer through which current is passed, the metal deformation by the EM becomes more severe.

### SUMMARY

A semiconductor integrated circuit capable of preventing the deformation of contacts and stably forming current paths is described herein.

In an embodiment of the present invention, a semiconductor integrated circuit includes: a driving unit configured to apply a power supply voltage to a drive node in response to a control signal; a first current path configured to couple the drive node and an output node; and a second current path configured to couple the drive node and the output node. The first current path and the second current path are coupled in parallel between the drive node and the output node.

In an embodiment of the present invention, a semiconductor integrated circuit includes: a transistor having a gate configured to receive a control signal, a source configured to receive a power supply voltage, and a drain coupled to first and second contacts; a first resistor coupled between the first contact and a third contact; and a second resistor coupled between the second contact and a fourth contact. The third and fourth contacts are electrically coupled and the first resistor and the second resistor are coupled in parallel between the first and third contacts.

In an embodiment of the present invention, a semiconductor integrated circuit includes: an output driving unit configured to provide an output current to an output node based on data; an output data transmission unit configured to transmit the output current through a plurality of current paths; and a pad configured to receive the output current transmitted through the output data transmission unit. The amount of current transmitted through each current path is inverse proportional to the number of current paths.

In an embodiment of the present invention, a semiconductor integrated circuit includes: a pull-up driving unit configured to provide a power supply voltage to a first drive node based on data; a first current path configured to couple the first drive node and an output node; a second current path configured to couple the first drive node and the output node; a pull-down driving unit configured to provide a ground voltage to a second drive node based on the data; a third current path configured to couple the second drive node and the output node; and a fourth current path configured to couple the second drive node and the output node.

### BRIEF DESCRIPTION OF THE DRAWINGS

Features, aspects, and embodiments are described in conjunction with the attached drawings, in which:

FIG. 1 schematically illustrates the configuration of a driving circuit used in a known semiconductor integrated circuit;

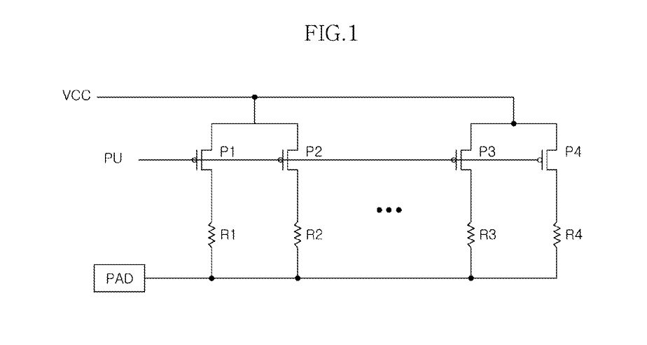

FIG. 2 illustrates the layout of the driving circuit of FIG. 1;

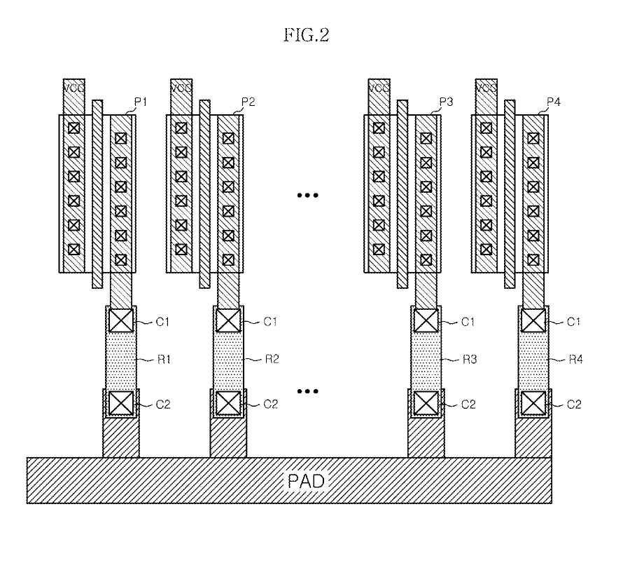

FIG. 3 schematically illustrates the configuration of a semiconductor integrated circuit according to an embodiment of the present invention;

FIG. 4 illustrates the layout of the semiconductor integrated circuit of FIG. 3; and

FIG. 5 schematically illustrates the configuration of a semiconductor integrated circuit according to an embodiment of the present invention.

### DETAILED DESCRIPTION

Hereinafter, a semiconductor integrated circuit according to the present invention will be described below with reference to the accompanying drawings through exemplary embodiments.

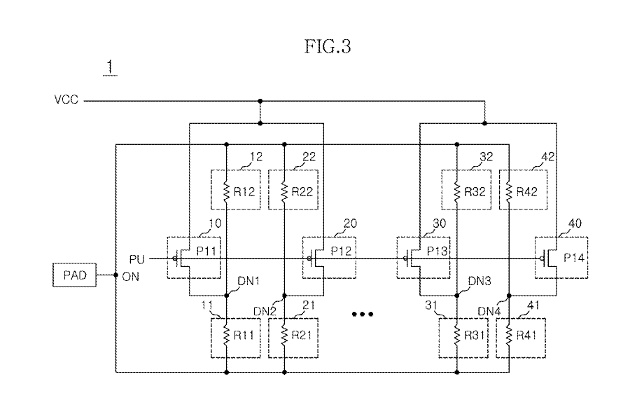

FIG. 3 schematically illustrates the configuration of a semiconductor integrated circuit according to an embodiment of the present invention. In FIG. 3, the semiconductor integrated circuit 1 includes a driving unit 10, first and second current paths 11 and 12, and a pad PAD. The driving unit 10 is coupled to the first and second current paths 11 and 12 through a drive node DN1, and the pad PAD is coupled to the first and second current paths 11 and 12 through an output node ON.

The driving unit 10 is configured to apply a power supply voltage VCC to the drive node DN1 in response to the control signal PU. The control signal PU is a signal for controlling whether or not to activate the driving unit 10. For example, when the semiconductor integrated circuit 1 is used as a data driving circuit, the control signal PU may correspond to data.

The driving unit 10 includes a first transistor P11. The first transistor P11 has a gate configured to receive the control signal PU, a source configured to receive the power supply voltage VCC, and a drain coupled to the drive node DN1. Here, the first transistor P11 is configured to pull the drive node DN1 up to the level of the power supply voltage VCC in response to the control signal PU, and thus a PMOS transistor may be used as the first transistor P11. Therefore, when the first transistor P11 is turned on in response to the control signal PU, the first transistor P11 applies the power supply voltage VCC to the drive node DN1.

The first and second current paths 11 and 12 are configured to provide the power supply voltage VCC applied from the driving unit 10 to the output node ON. The first and second current paths 11 and 12 are configured to transmit a current generated by applying the power supply voltage VCC. The first and second current paths 11 and 12 divide and transmit the current generated by the application of the power supply voltage VCC. In an embodiment of the present invention, the first and second current paths 11 and 12 may have the same resistance value. Therefore, the amount of current transmitted through the first and second current paths 11 and 12 corresponds to ½ of the amount of current transmitted through one current path. In an embodiment of the present invention, the number of current paths may vary. That is, the driving unit 10 may include three or more current paths. As the number of current paths increases, the amount of current per each current path decreases.

The first and second current paths 11 and 12 include first and second resistors R11 and R12 coupled between the drive node DN1 and the output node ON, respectively. The first and second resistors R11 and R12 may have the same resistance value.

In FIG. 3, the semiconductor integrated circuit 1 may include a plurality of components configured to perform the same function as the driving unit 10 and the first and second current paths 11 and 12 which have been described above. FIG. 3 illustrates that additional driving units 20 to 40 include second to fourth transistors P12 to P14, respectively, and current paths 21, 22, 31, 32, 41, and 42 for coupling the additional driving units 20 to 40 and the pad PAD include third to eighth resistors R21, R22, R31, R32, R41, and R42, respectively. However, the number of the driving units and the current paths may vary, i.e., the semiconductor integrated circuit 1 may include only the driving unit 10 and the first and second current paths 11 and 12 or may also include more driving units and current paths. The semiconductor integrated circuit 1 according to an embodiment of the present invention includes a plurality of paths through which currents driven by the driving units 10 to 40 are transmitted. Therefore, a failure which may be caused by EM occurring while an excessive current is passed may be reduced.

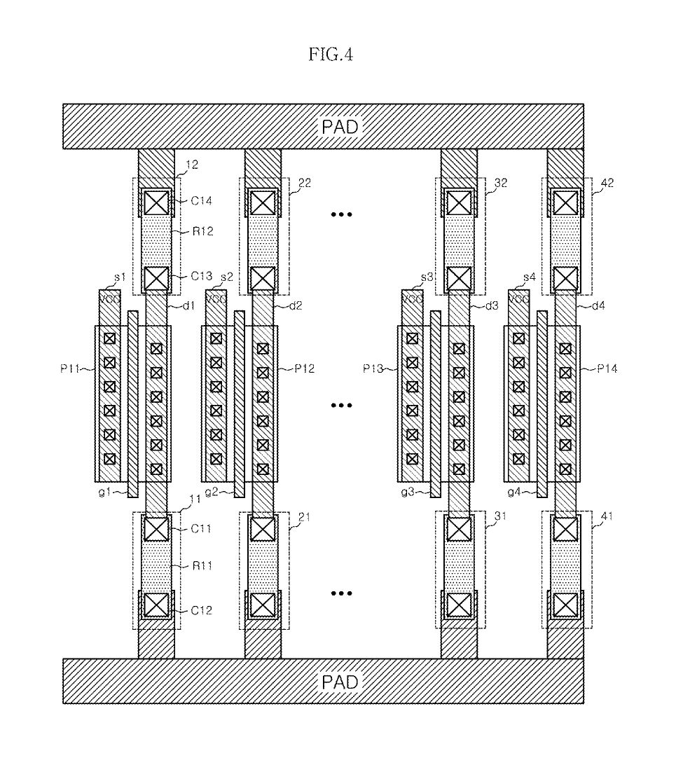

FIG. 4 illustrates the layout of the semiconductor integrated circuit 1 of FIG. 3. In FIG. 4, the semiconductor integrated circuit includes the first to fourth transistors P11 to P14 and the first to eighth current paths 11, 12, 21, 22, 31, 32, 41, and 42. The first to fourth transistors P11 to P14 correspond to the driving units 10 to 40 of FIG. 3. The first transistor P11 is coupled to the pad PAD through the first and second current paths 11 and 12. The first transistor P11 is configured to receive the control signal PU of FIG. 3 through a gate g1 and receive the power supply voltage VCC through a source s1. The drain d1 of the first transistor P11 is coupled to the first and second current paths 11 and 12 through first and third contacts C11 and C13. Referring to FIG. 4, the first transistor p11 is coupled to the first and second current paths 11 and 12 at both ends of the drain d1. Therefore, the first and third contacts C11 and C13 may be formed at both ends of the drain d1 of the first transistor P11. The first and second current paths 11 and 12 are coupled to the pad PAD through second and fourth contacts C12 and C14, respectively. The first and second current paths 11 and 12 may include the resistors R11 and R12 composed of poly resistors (e.g., polysilicon material). The first to fourth metal contacts C11 to C14 may include metal contacts, and may be formed in various manners. Through the above-described configuration, the current generated by applying the power supply voltage VCC through the first transistor P11 is divided and transmitted to the pad PAD through the first and second current paths 11 and 12. Therefore, a failure caused by the EM may be reduced. That is, the amount of current flowing through the first and second current paths 11 and 12 is reduced and thus a probability of deformations of the first to fourth contacts C11 to C14 caused by the EM may decrease.

The second transistor P12 is coupled to the pad PAD through the contacts and the third and fourth current paths 21 and 22. The third transistor P13 is coupled to the pad PAD through the contacts and the fifth and sixth current paths 31 and 32. The fourth transistor P14 is coupled to the pad PAD through the contacts and the seventh and eighth current paths 41 and 42. As such, the semiconductor integrated circuit according to an embodiment of the present invention increases the number of current paths and reduces the amount of current transmitted through each current path.

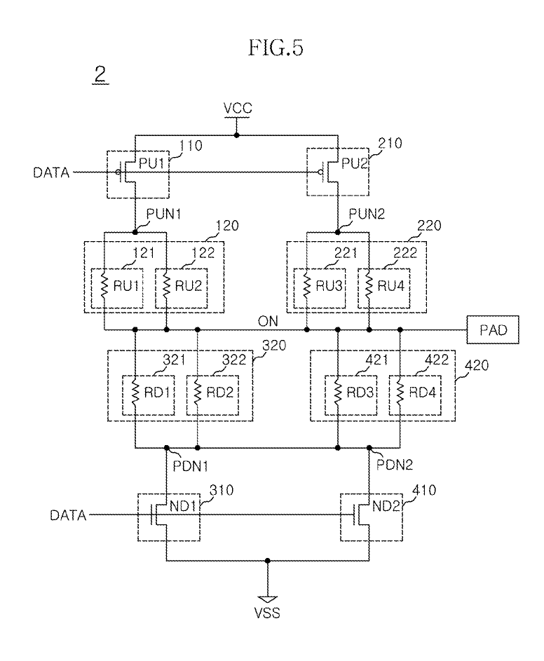

FIG. 5 schematically illustrates the configuration of a semiconductor integrated circuit according to an embodiment of the present invention. FIG. 5 illustrates an example in which the semiconductor integrated circuit 2 is applied to a data driving circuit. The semiconductor integrated circuit 2 includes first and second pull-up driving units 110 and 210, first and second pull-up data transmission units 120 and 220, first and second pull-down driving units 310 and 410, and first and second pull-down data transmission units 320 and 420.

The first pull-up driving unit 110 is configured to provide a power supply voltage VCC to a first pull-up drive node PUN1 based on data DATA. The first pull-up driving unit 110 includes a first pull-up transistor PU1. The first pull-up transistor PU1 is configured to receive the data DATA through a gate thereof and receive the power supply voltage VCC through a source thereof. The drain of the first pull-up transistor PU1 is coupled to the first pull-up data transmission unit 120 through the first pull-up drive node PUN1.

The first pull-up data transmission unit 120 includes first and second current paths 121 and 122. The first and second current paths 121 and 122 are configured to couple the first pull-up drive node PUN1 and an output node ON. The first current path 121 includes a first pull-up resistor RU1 and couples the first pull-up drive node PUN1 and the output node ON. The second current path 122 includes a second pull-up resistor RU2 and couples the first pull-up drive node PUN1 and the output node ON. FIG. 5 illustrates that the first pull-up data transmission unit 120 includes two current paths. In an embodiment of the present invention, the first pull-up data transmission unit 120 may include three or more current paths. As the number of current paths included in the first pull-up data transmission unit 120 increases, the amount of current transmitted through each current path decreases.

The first pull-up transistor PU1 may include a PMOS transistor. When the data DATA is at a low level, the first pull-up transistor PU1 is turned on to apply the power supply voltage VCC to the first pull-up drive node PUN1. The first and second current paths 121 and 122 divide and transmit the current generated by applying the power supply voltage VCC. When the first and second pull-up resistors RU1 and RU2 forming the first and second current paths 121 and 122 have the same resistance value, each of the first and second current paths 121 and 122 transmits the half of the current generated by applying the power supply voltage VCC.

The second pull-up driving unit 210 includes a second pull-up transistor PU2, and the second pull-up data transmission unit 220 includes third and fourth current paths 221 and 222. The third and fourth current paths 221 and 222 include third and fourth pull-up resistors RU3 and RU4, and couple a second pull-up drive node PUN2 and the output node ON. The second pull-up driving unit 210 and the third and fourth current paths 221 and 222 may have the same structure and perform the same function as the first pull-up driving unit 110 and the first and second current paths 121 and 122.

The first pull-down driving unit 310 is configured to provide a ground voltage VSS to a first pull-down drive node PDN1 based on the data DATA. The first pull-down driving unit 310 includes a first pull-down transistor ND1. The first pull-down transistor ND1 is configured to receive the data DATA through a gate thereof and receive the ground voltage VSS through a source thereof. The drain of the first pull-down transistor ND1 is coupled to the first pull-down data transmission unit 320 through the first pull-down drive node PDN1.

The first pull-down data transmission unit 320 includes fifth and sixth current paths 321 and 322. The fifth and sixth current paths 321 and 322 are configured to couple the first pull-down drive node PDN1 and the output node ON. The fifth current path 321 includes a first pull-down resistor RD1 and couples the first pull-down drive node PDN1 and the output node ON. The sixth current path 322 includes a second pull-down resistor RD2 and couples the first pull-down drive node PDN1 and the output node ON. In an embodiment of the present invention, the first pull-down data transmission unit 320 may include three or more current paths. As the number of current paths included in the first pull-down data transmission unit 320 increases, the amount of current transmitted through each current path decreases.

The first pull-down transistor ND1 may include an NMOS transistor, for example. When the data DATA is at a high level, the first pull-down transistor ND1 is turned on to change the voltage of the first pull-down drive node PDN1 to a ground voltage level VSS. That is, the first pull-down transistor ND1 may allow a current to flow from the pull-down drive node PDN1 to the ground voltage terminal so that the first pull-down drive node PND1 becomes the ground voltage level VSS. When the first pull-down transistor ND1 is turned on, a sink current is passed through fifth and sixth current paths 321 and 322 coupling the output node ON and the first pull-down drive node PDN1. Since the sink current is divided and transmitted through the fifth and sixth current paths 321 and 322, the amount of current flowing through the fifth and sixth current paths 321 and 322 may be reduced.

The second pull-down driving unit 410 includes a second pull-down transistor ND2, and the second pull-down data transmission unit 420 includes the seventh and eighth current paths 421 and 422. The seventh and eighth current paths 421 and 422 include third and fourth pull-down resistors RD3 and RD4, respectively, and couple a second pull-down drive node PND2 and the output node ON. The second pull-down driving unit 410 and the seventh and eighth current paths 421 and 422 may have the same structure and perform the same function as the first pull-down driving unit 310 and the fifth and sixth current paths 321 and 322.

While certain embodiments have been described above, it will be understood to those skilled in the art that the embodiments described are by way of example only. Accordingly, the semiconductor integrated circuit described herein should not be limited based on the described embodiments. Rather, the semiconductor integrated circuit described herein should only be limited in light of the claims that follow when taken in conjunction with the above description and accompanying drawings.

What is claimed is:

1. A semiconductor integrated circuit comprising:
a driving unit configured to apply a power supply voltage to a drive node in response to a control signal;
a first current path configured to couple the drive node and an output node; and
a second current path configured to couple the drive node and the output node,
wherein the first current path and the second current path are coupled in parallel between the drive node and the output node.

2. The semiconductor integrated circuit according to claim 1, wherein the first current path comprises:
is a first contact coupled to the drive node;
a second contact coupled to the output node; and
a resistor coupled between the first contact and second contact.

3. The semiconductor integrated circuit according to claim 2, wherein the second current path comprises:
a third contact coupled to the drive node;
a fourth contact coupled to the output node; and
a resistor coupled between the third and fourth contacts.

4. The semiconductor integrated circuit according to claim 1, wherein the first and second current paths have substantially the same resistance value.

5. A semiconductor integrated circuit comprising:
a transistor having a gate configured to receive a control signal, a source configured to receive a power supply voltage, and a drain coupled to first and second contacts;
a first resistor coupled between the first contact and a third contact; and
a second resistor coupled between the second contact and a fourth contact,
wherein the third and fourth contacts are electrically coupled and the first resistor and the second resistor are coupled in parallel between the first and third contacts.

6. The semiconductor integrated circuit according to claim 5, wherein the first and second contacts are formed at both ends of the drain.

7. The semiconductor integrated circuit according to claim 5, wherein the first and second resistors have substantially the same resistance value.

8. A semiconductor integrated circuit comprising:
an output driving unit configured to provide an output current to an output node based on data;
an output data transmission unit configured to transmit the output current through a plurality of current paths; and
a pad configured to receive the output current transmitted through the output data transmission unit,
wherein the amount of current transmitted through each current path is inverse proportional to the number of current paths.

9. The semiconductor integrated circuit according to claim 8, wherein each of the current paths includes a resistor, and is coupled between the output driving unit and the pad through a contact.

10. A semiconductor integrated circuit comprising:
a pull-up driving unit configured to provide a power supply voltage to a first drive node based on data;
a first current path configured to couple the first drive node and an output node;
a second current path configured to couple the first drive node and the output node;
a pull-down driving unit configured to provide a ground voltage to a second drive node based on the data;
a third current path configured to couple the second drive node and the output node; and
a fourth current path configured to couple the second drive node and the output node.

11. The semiconductor integrated circuit according to claim 10, wherein each of the first and second current paths comprises a resistor coupled between the first drive node and the output node, and each of the third and fourth current paths comprises a resistor coupled between the second drive node and the output node.
